(19) United States
(12) Patent Application Publication
(10) Pub. No.: US 2007/0057329 A1
(43) Pub. Date: Mar. 15, 2007

(54) Semiconductor device having a p-MOS transistor with source-drain extension counter-doping

(76) Inventors: Sinan Goktepeli, Austin, TX (US); James D. Burnett, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/222,544

(22) Filed: Sep. 9, 2005

(51) Int. Cl. H01L 21/8238; H01L 29/76

(52) U.S. Cl. 257/371; 257/369; 438/199; 438/223; 257/374; 438/207

(57) ABSTRACT

A method for forming a semiconductor device is provided. The method includes forming a n-type well region. The method further includes forming a gate corresponding to the semiconductor device on top of the n-type well region. The method further includes forming a source-drain extension region on each side of the gate in the n-type well region using a p-type dopant. The method further includes doping the source-drain extension region on each side of the gate in the n-type well region using a n-type dopant such that the n-type dopant is substantially encompassed within the source-drain extension region. The method further includes forming a source and a drain corresponding to the semiconductor device.

### FIELD OF THE INVENTION

The present invention relates generally to semiconductor devices, and more particularly to a semiconductor device with source-drain extension counter-doping.

### RELATED ART

Increasingly lower-power semiconductor devices are needed to reduce power requirements of integrated circuits, such as memories. Memory devices, such as SRAMS, are typically implemented using bitcells, whose performance is a function of many parameters including semiconductor techniques used to implement the bitcells. SRAM bitcell functionality and performance, among other things, depends on the write margin of the bitcell. Higher write margin enables one to change the status of a bitcell using a lower voltage. Lower voltage correspondingly results in lower power consumption by the bitcell and thus the memory using the bitcell. However, conventional memory devices require higher voltage to perform a status change of the bitcell resulting in higher power consumption.

Thus, there is a need for an improved semiconductor device that results in a higher write margin for bitcells for memory devices, such as SRAMs.

### BRIEF DESCRIPTION OF THE DRAWINGS

The present invention is illustrated by way of example and not limited by the accompanying figures, in which like references indicate similar elements, and in which:

FIG. 1 is a drawing of a semiconductor device with a n-type well region and a p-type well region, consistent with a process step of one embodiment of the invention;

FIG. 2 is a drawing of a semiconductor device of FIG. 1 with gates formed on top of the n-type well region and the p-type well region, respectively, consistent with a process step of one embodiment of the invention;

FIG. 3 is a drawing of a semiconductor device of FIG. 2 with source-drain extension regions formed, consistent with a process step of one embodiment of the invention;

FIG. 4 is a drawing of a semiconductor device of FIG. 3 with the source-drain extension region on each side of the gate in the n-type well region being doped using a n-type dopant, consistent with a process step of one embodiment of the invention; and

FIG. 5 is a drawing of a semiconductor device of FIG. 4 with spacers, source, and drain regions, consistent with a process step of one embodiment of the invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE EMBODIMENTS

In one aspect, a method for forming a semiconductor device is provided. The method includes forming a n-type well region. The method further includes forming a gate corresponding to the semiconductor device on top of the n-type well region. The method further includes forming a source-drain extension region on each side of the gate in the n-type well region using a p-type dopant. The method further includes doping the source-drain extension region on each side of the gate in the n-type well region using a n-type dopant such that the n-type dopant is substantially encompassed within the source-drain extension region. The method further includes forming a source and a drain corresponding to the semiconductor device.

In another aspect, a semiconductor device including a n-type well region and a gate corresponding to the semiconductor device on top of the n-type well region is provided. The semiconductor device may further include a source-drain extension region on each side of the gate in the n-type well region formed using a p-type dopant, where the source-drain extension region on each side of the gate in the n-type well region is further doped using a n-type dopant such that the n-type dopant is substantially encompassed within the source-drain extension region. The semiconductor device may further include a source and a drain corresponding to the semiconductor device.

In yet another aspect, a semiconductor device including a p-type well region and a gate corresponding to the semiconductor device on top of the p-type well region is provided. The semiconductor device may further include a source-drain extension region on each side of the gate in the p-type well region formed using a n-type dopant, where the source-drain extension region on each side of the gate in the p-type well region is further doped using a p-type dopant such that the p-type dopant is substantially encompassed within the source-drain extension region. The semiconductor device may further include a source and a drain corresponding to the semiconductor device.

FIG. 1 is a drawing of a semiconductor device with a n-type well region and a p-type well region, consistent with one embodiment of the invention. Using semiconductor processing techniques, such as ion implantation, in a p-type substrate, a n-type well region 14 and a p-type well region 16 may be formed. The n-type well region 14 and the p-type well region 16 may be separated by a dielectric 18 which may serve as a shallow trench isolation. Although FIG. 1 shows both n-type and p-type well regions, embodiments of the present invention may be implemented without the p-type well region.

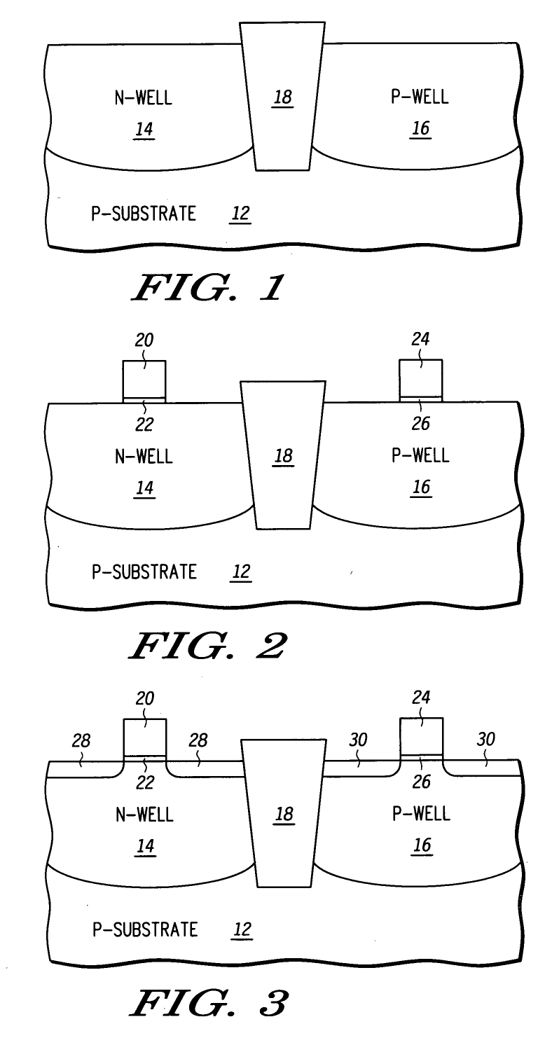

FIG. 2 is a drawing of a semiconductor device of FIG. 1 with gates formed on top of the n-type well region and the p-type well region, respectively, consistent with one embodiment of the invention. Next, consistent with semiconductor processing techniques, a gate 20 along with dielectric 22 may be formed on top of the n-type well region 14. At the same time, another gate 24 along with dielectric 26 may be formed on top of the p-type well region 16. If the semiconductor device does not include a p-type well region then gate 24 and dielectric 26 may not be formed.

FIG. 3 is a drawing of a semiconductor device of FIG. 2 with source-drain extension regions formed, consistent with one embodiment of the invention. Next, a source-drain extension region 28 may be formed on each side of gate 20 and another source-drain extension region 30 may be formed on each side of gate 24. Source-drain extension region 28 may be formed by implanting p-type ions, such as boron, BF2, indium, gallium, and other suitable dopants. During formation of source-drain extension region 28, the p-type well region 16 may be covered by a photoresist (not shown). Source-drain extension region 30 may be formed by implanting n-type ions, such as arsenic, phosphorus, antimony, and other suitable dopants. During formation of source-drain extension region 30, the n-type well region may be covered by a photoresist (not shown). Although not shown, halo implantations may be performed at this processing stage.

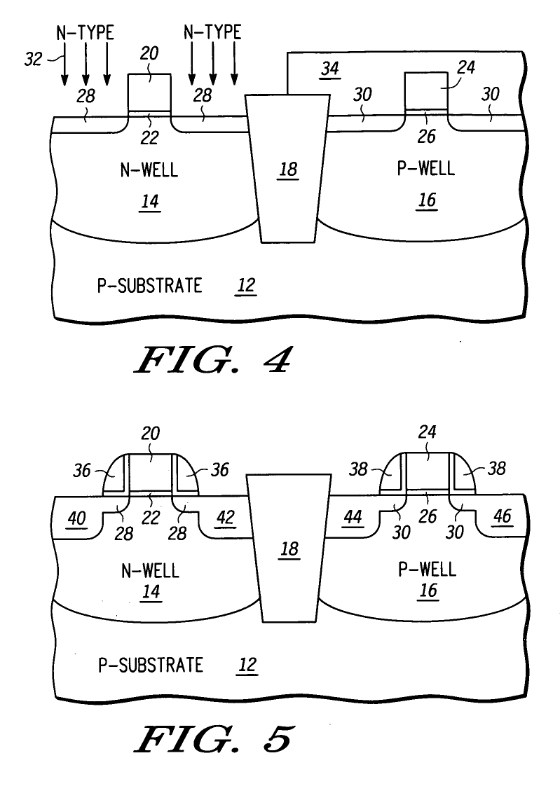

FIG. 4 is a drawing of a semiconductor device of FIG. 3 with the source-drain extension region on each side of the gate in the n-type well region being doped using a n-type dopant consistent with one embodiment of the invention. Next, as shown in FIG. 4, the source-drain extension region 28 in the n-type well region 14 may be doped using a n-type dopant, such that the n-type dopant is substantially encompassed within the source-drain extension region. During this processing step, p-type well region may be covered using photoresist 34. By way of example, this step may be performed using the same mask as used to form the source-drain extension region. The n-type dopant increases the net active concentration in the source-drain extension region resulting in a higher source-drain extension resistance. This in turn lowers the on current of the semiconductor device while having minimal effect on the threshold voltage of the semiconductor device. Accordingly, when used as a load device in a SRAM bitcell, this weaker device results in a lower voltage needed to write the bitcell.

In one embodiment, only certain selected semiconductor devices in an integrated circuit may be subjected to this processing step. Thus, for example, non-selected semiconductor devices may not be doped using the n-type dopant as part of this processing step. In one embodiment, the selected semiconductor devices may relate to a SRAM formed as part of a microprocessor. By selectively doping the pMOS load devices that are part of the SRAM, the write margin for the SRAM may be improved without affecting other pMOS devices comprising the microprocessor. In particular, the minimum voltage required to change a state of the SRAM may be lowered. The minimum voltage may be lowered because of lowering of the on-state current of the pMOS device. This process step, however, has minimum effect on other pMOS device parameters, such as threshold voltage, off-state leakage current, and overlap capacitance. Thus, this allows a SRAM employing this pMOS device to perform other operations, such as read operation normally.

In one embodiment, the n-type dopant used as part of this step may be arsenic. Alternatively, phosphorus, antimony, or similar suitable dopants may be used. By way of example, the implantation energy of the n-type dopant may be in a range between 1 to 6 keV. By way of example, the dosage of the n-type dopant may be in a range between 5e13 atoms per square centimeter to 1e14 atoms per square centimeter.

FIG. 5 is a drawing of a semiconductor device of FIG. 4 with spacers, source, and drain regions consistent with one embodiment of the invention. As part of this processing step, spacers 36 and 38 may be formed. Additionally, a source 40 and a drain 42 may be formed in the n-type well region 14. Further, a source 44 and a drain 46 may be formed in the p-type well region 16.

Although the above process and the semiconductor device is described using exemplary counter-doping of a pMOS device, a nMOS device may also be counter-doped using a similar process. The counter-doping may result in a lowering of the on-state current of the nMOS device. The source-drain extension region of the nMOS device may be counter-doped using a p-type dopant, such as boron, BF2, indium, gallium, and other suitable dopants. By way of example, the implantation energy of the p-type dopant may be in a range between 1 to 6 keV. By way of example, the dosage of the p-type dopant may be in a range between 5e13 atoms per square centimeter to 1e14 atoms per square centimeter. The weaker nMOS device may improve the write margin of a SRAM that employs the weaker nMOS device as a load device.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method of making a semiconductor device comprising:
forming a n-type well region;
forming a gate corresponding to the semiconductor device on top of the n-type well region;
forming a source-drain extension region on each side of the gate in the n-type well region using a p-type dopant;
doping the source-drain extension region on each side of the gate in the n-type well region using a n-type dopant such that the n-type dopant is substantially encompassed within the source-drain extension region; and
forming a source and a drain corresponding to the semiconductor device.

2. The method of claim 1, wherein the n-type dopant is arsenic.

3. The method of claim 1, wherein an implantation energy of the n-type dopant is in a range between 1 to 6 keV.

4. The method of claim 1, wherein a dopant dosage of the n-type dopant is in a range between 5e13 atoms per square centimeter to 1e14 atoms per square centimeter.

5. The method of claim 1, wherein the n-type dopant is at least one of phosphorous and antimony.

6. The method of claim 1, wherein doping the source-drain extension region on each side of the gate in the n-type well region using the n-type dopant step is performed using a mask used to form the source-drain extension region on each side of the gate in the n-type well region using the p-type dopant.

7. A semiconductor device comprising:
a n-type well region;
a gate corresponding to the semiconductor device formed on top of the n-type well region;
a source-drain extension region formed, on each side of the gate in the n-type well region, using a p-type dopant, wherein the source-drain extension region on each side of the gate in the n-type well region is further doped using a n-type dopant such that the n-type dopant is substantially encompassed within the source-drain extension region; and
a source and a drain corresponding to the semiconductor device.

8. A SRAM comprising the semiconductor device of claim 7.

9. The semiconductor device of claim 7, wherein the n-type dopant is arsenic.

10. The semiconductor device of claim 7, wherein an implantation energy of the n-type dopant is in a range between 1 to 6 keV.

11. The semiconductor device of claim 7, wherein a dopant dosage of the n-type dopant is in a range between 5e13 atoms per square centimeter to 1e14 atoms per square centimeter.

12. The semiconductor device of claim 7, wherein the n-type dopant is at least one of phosphorous and antimony.

13. A semiconductor device comprising:
a p-type well region;
a gate corresponding to the semiconductor device formed on top of the p-type well region;
a source-drain extension region formed, on each side of the gate in the p-type well region, using a n-type dopant, wherein the source-drain extension region on each side of the gate in the p-type well region is further doped using a p-type dopant such that the p-type dopant is substantially encompassed within the source-drain extension region; and
a source and a drain corresponding to the semiconductor device.

14. The semiconductor device of claim 13, wherein the p-type dopant is boron.

15. The semiconductor device of claim 13, wherein an implantation energy of the p-type dopant is in a range between 1 to 6 keV.

16. The semiconductor device of claim 13, wherein a dopant dosage of the p-type dopant is in a range between 5e13 atoms per square centimeter to 1e14 atoms per square centimeter.

17. The semiconductor device of claim 13, wherein the p-type dopant is at least one of BF2, indium, and gallium.

18. A SRAM comprising the semiconductor device of claim 13.
